(19) United States
(12) Patent Application Publication
(10) Pub. No.: US 2022/0255141 A1
(43) Pub. Date: Aug. 11, 2022

(54) BATTERY CONNECTION MODULE

(71) Applicant: Molex, LLC, Lisle, IL (US)

(72) Inventors: Yun-Jin LI, Chengdu (CN); Sheau-Noan CHEONG, Jurong Town (SG); Kian-Heng LIM, Jurong Town (SG); Shang-Xiu Zeng, Chengdu (CN)

(73) Assignee: Molex, LLC, Lisle, IL (US)

(21) Appl. No.: 17/582,012

(22) Filed: Jan. 24, 2022

(30) Foreign Application Priority Data
Feb. 9, 2021 (CN) 202110177438.7

(51) Int. Cl. H01M 10/42; H01M 10/48; H01M 50/502; H05K 3/32

(52) U.S. Cl. CPC H01M 10/425; H01M 10/482; H05K 2201/10037; H05K 3/325; H01M 50/502

(57) ABSTRACT

A battery connection module is provided and is adapted to connect a plurality of batteries, the battery connection module includes busbars, a circuit board and bridging pieces. The busbars are used to be connected to the batteries. The bridging pieces are connected between the corresponding busbars and the circuit board, each bridging piece has a circuit board connection segment and a busbar connection segment which are arranged along a straight direction and are respectively connected to the circuit board and the corresponding busbar and a buffering segment which is positioned between the circuit board connection segment and the busbar connection segment, the buffering segment includes at least two buffering strips, the at least two buffering strips are constructed as symmetry in a transverse direction with respect to a central line extending along the straight direction, each buffering strip has at least one curving portion.

### RELATED APPLICATIONS

This application claims priority to Chinese Patent Application Serial No. 202110177438.7, filed Feb. 9, 2021, which is incorporated herein by reference in its entirety.

### TECHNICAL FIELD

The present disclosure relates to a battery connection module, and particularly relates to a battery connection module which makes a busbar and a circuit board connected by a bridging piece.

### BACKGROUND ART

Chinese disclosure patent application issuance publication No. CN102859755B discloses an energy storage module, voltage taps of the energy storage module are constructed as flexible movement compensating elements and are used to compensate relative movement of a wiring element relative to a cell connector of and/or are used to compensate different expansions of the wiring element and the cell connector during operation of the energy storage module. A first end of the voltage tap is provided in a first connecting segment, and a second end of the voltage tap is provided in a second connecting segment, the first connecting segment and the second connecting segment are adjoined to each other, and the first connecting segment is provided at an angle of 45 degrees to 135 degrees from the second connecting segment. The first connecting segment and the second connecting segment are provided with slots for transition from each other and one grooved segment protruding from a plane where the voltage tap is present. In addition, the first end of each voltage tap has at least one leg protruding the corresponding plane of the voltage tap. The grooved segment of the voltage tap is constructed to bend from the plane of the voltage tap so as to be used to compensate relative movement which is generated by expansion and is in a direction facing a board surface, but only the first connecting segment needs to be provided by the angle of 45-135 degrees from the second connecting segment, can relative movement in the direction facing a board thickness direction and a generated shear force therefrom be compensated.

Chinese disclosure patent application publication No. CN110459888A discloses a connecting assembly, a conductive terminal of the connecting assembly includes a fixing portion, a contacting portion electrically connected with a corresponding battery cell and a connecting arm connecting the fixing portion and the contacting portion, the connecting arm has a flat plate portion and a bending portion and is provided in form of curve shape to be elastically connected between a base portion and the contacting portion. The fixing portion of the conductive terminal has the base portion which is electrically connected with the circuit board and a fixing leg and a welding portion which are formed to bend from the base portion and extend. However, the bending portion is a bending part which protrudes along a board surface direction, is used to compensate a shear force in a direction facing a board thickness direction, but a bearing strength of the bending portion is weaker with respect to relative movement generated in the direction facing the board surface due to expansion.

The constructions in the above two prior arts still have a deficiency in compensating relative movement between the two components and expansion. A battery pack provides a power supply for an electrical automobile, it is particularly important to monitor each performance of the battery pack. A battery connection module basically includes a circuit board, a bus connecting battery cells and connecting members connected between the circuit board and the bus. During assembling, what is difficult is that there is significant relative movement generated between the bus and the circuit board when the bus is welded to the battery cell. In operation state, each component of the battery connection module and each battery of a battery unit will movement relatively; in addition to expansion generated by chemical reaction of the battery, in alternately varied circumstance temperatures, temperature difference between each battery of the battery unit also causes such a movement, in addition, such a movement also is generated due to a certain suffered impact during vibration, in turn a process that the battery connection module collects a signal becomes unstable, service life of the battery connection module becomes shorten. Therefore, the connecting member between the circuit board and the bus needs to be capable of ensuring compensation for movement due to statically suffered force and movement in dynamic form, so that the battery connection module can stably collect a signal and have a longer service life.

### SUMMARY

Therefore, one object of the present disclosure is to provide a battery connection module which can improve at least one deficiency in the prior art.

Accordingly, in some embodiments, a battery connection module of the present disclosure is adapted to connect a plurality of batteries, the battery connection module comprises busbars, a circuit board and bridging pieces. The busbars are used to be connected to the batteries. The bridging pieces are connected between the corresponding busbars and the circuit board, each bridging piece has a circuit board connection segment and a busbar connection segment which are arranged along a straight direction and are respectively connected to the circuit board and the corresponding busbar and a buffering segment which is positioned between the circuit board connection segment and the busbar connection segment, the buffering segment comprises at least two buffering strips, the at least two buffering strips are constructed as symmetry in a transverse direction with respect to a central line extending along the straight direction, each buffering strip has at least one curving portion.

In some embodiments, there are steps between a plane where the buffering segment is present and a plane where the circuit board connection segment is present and a plane where the busbar connection segment is present, two ends of each buffering strip of the buffering segment are respectively connected to the circuit board connection segment and the busbar connection segment via two step connecting portions.

In some embodiments, the buffering segment include two buffering strips, each buffering strip has at least two straight direction curving portions which are positioned in the same plane and continuously curve reversely relative to each other in the straight direction.

In some embodiments, the two step connecting portions connected to the circuit board connection segment are positioned at outer sides relative to the two step connecting portions connected to the busbar connection segment, the two step connecting portions connected to the busbar connection segment are positioned at inner sides relative to the two step connecting portions connected to the circuit board connection segment, the at least two straight direction curving portions of each buffering strip are positioned between the step connecting portion connected to the circuit board connection segment and the step connecting portion connected to the busbar connection segment.

In some embodiments, each buffering strip further has at least one transverse curving portion which is spaced apart from the at least two straight direction curving portions and protrudes laterally and outwardly along the transverse direction.

In some embodiments, the bridging piece further has a plurality of protective pieces which are integrally formed to the circuit board connection segment and the busbar connection segment and protrude toward the plane where the buffering segment is present.

In some embodiments, a plane where the buffering segment is present is positioned in the same plane with a plane where the circuit board connection segment is present and a plane where the busbar connection segment is present.

In some embodiments, the buffering segment comprises two buffering strips, each buffering strip has at least two straight direction curving portions which are positioned in the same plane and continuously curve reversely relative to each other in the straight direction.

In some embodiments, the buffering segment comprises two buffering strips, each buffering strip has at least two transverse curving portions which are positioned in the same plane and alternately protrude inwardly or outwardly in the transverse direction.

In some embodiments, the buffering segment comprises at least two buffering strips, a plane where each buffering strip of the buffering segment is present is perpendicular to a plane where the circuit board connection segment is present and a plane where the busbar connection segment is present.

In some embodiments, each buffering strip is formed with an opened groove.

In some embodiments, the circuit board connection segment of the bridging piece has a plate and two raising legs which are formed to the plate and are used to be bridged onto the circuit board, the two raising legs raise the plate and make the plate and the circuit board spaced apart from each other by a certain distance.

In some embodiments, the circuit board connection segment of the bridging piece further has a supporting elastic piece which is formed to the plate and is used to abut against the circuit board, the supporting elastic piece raises the plate and makes the plate and the circuit board spaced apart from each other by the certain distance.

In some embodiments, the circuit board connection segment of the bridging piece has a plurality of welding apertures.

In some embodiments, the circuit board connection segment of the bridging piece has a welding leg, the circuit board is formed with a welding insertion hole corresponding to the welding leg.

In some embodiments, the circuit board connection segment of the bridging piece has an opening used to provide a sensor therein.

The battery connection module of the present disclosure provides a bridging piece which has higher deformation capability and better anti-vibration effect and promotes compensation capability of the bridging piece for relative movement between the corresponding circuit board and the busbar and expansion of the corresponding batteries. Furthermore, the welding apertures and the welding leg of the circuit board connection segment of the bridging piece promote welding holding force between the circuit board connection segment of the bridging piece and the circuit board.

### BRIEF DESCRIPTION OF THE DRAWINGS

Other features and technical effects of the present disclosure will be apparent in an embodiment referring to the accompanying drawings, in which:

FIG. 1 is a perspective view of a first embodiment of a battery connection module of the present disclosure and a battery set and an end plate;

FIG. 2 is a perspective exploded view of the first embodiment;

FIG. 3 is a partial perspective view of the first embodiment;

FIG. 4 is a partial perspective exploded view of FIG. 3;

FIG. 5 is a partial perspective exploded view of a circuit board and a bridging piece of the first embodiment;

FIG. 6 is a further partial perspective exploded view on a basis of FIG. 5;

FIG. 7 is a top view the of the bridging piece of the first embodiment;

FIG. 8 is a side view the of the bridging piece of the first embodiment;

FIG. 9 is a perspective view of a bridging piece of a second embodiment of the connection module of the present disclosure battery;

FIG. 10 is a top view of the bridging piece of the second embodiment;

FIG. 11 is a perspective view of a bridging piece of a third embodiment of the connection module of the present disclosure battery;

FIG. 12 is a top view of the bridging piece of the third embodiment;

FIG. 13 is a perspective view of a bridging piece of a fourth embodiment of the connection module of the present disclosure battery;

FIG. 14 is a perspective view of a bridging piece of a fifth embodiment of the connection module of the present disclosure battery;

FIG. 15 is a perspective view of a bridging piece of a sixth embodiment of the connection module of the present disclosure battery;

FIG. 16 is a perspective view of a bridging piece of a seventh embodiment of the connection module of the present disclosure battery;

FIG. 17 is a side view of the bridging piece of the seventh embodiment;

FIG. 18 is a partial perspective view of the bridging piece, a circuit board and a busbar of the seventh embodiment; and

FIG. 19 is a side view of the seventh embodiment of FIG. 18.

### DETAILED DESCRIPTION OF THE PREFERRED EMBODIMENTS

Before the present disclosure is described in detail, it is noted that the similar components are indicated by the same reference numerals in the following description.

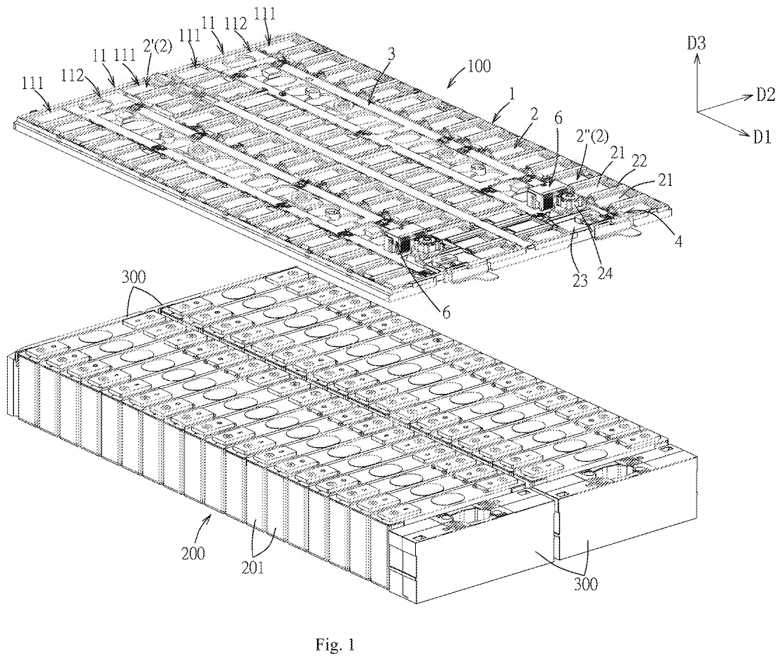

Referring to FIG. 1 to FIG. 4, a first embodiment of a battery connection module 100 of the present disclosure is adapted to be electrically connected to a battery set 200, the battery set 200 has a plurality of batteries 201, in the first embodiment, the plurality of batteries 201 are arranged as two rows. Two ends of the battery set 200 are provided with a plurality of end plates 300. The battery connection module 100 includes a carrying tray 1, a plurality of busbars 2, two circuit boards 3 and a plurality of bridging pieces 4.

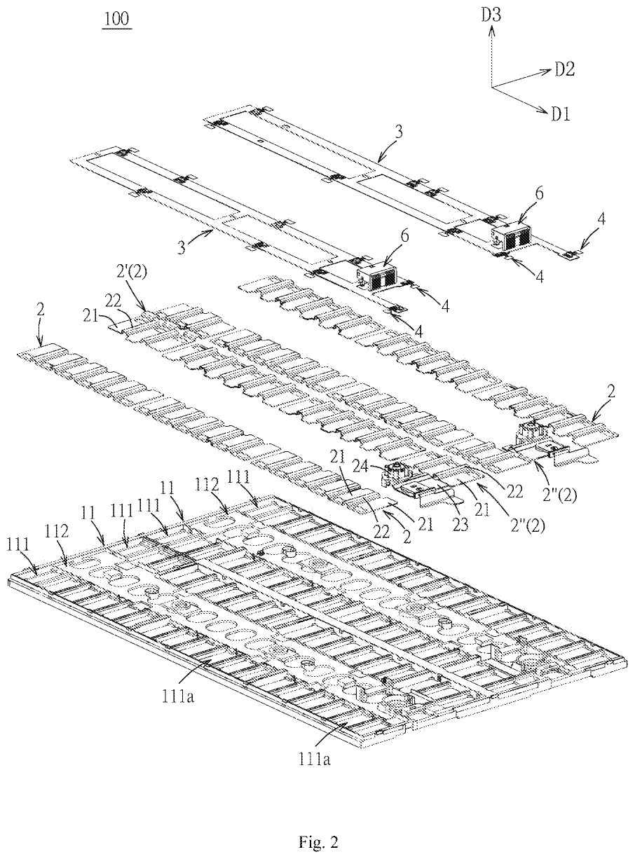

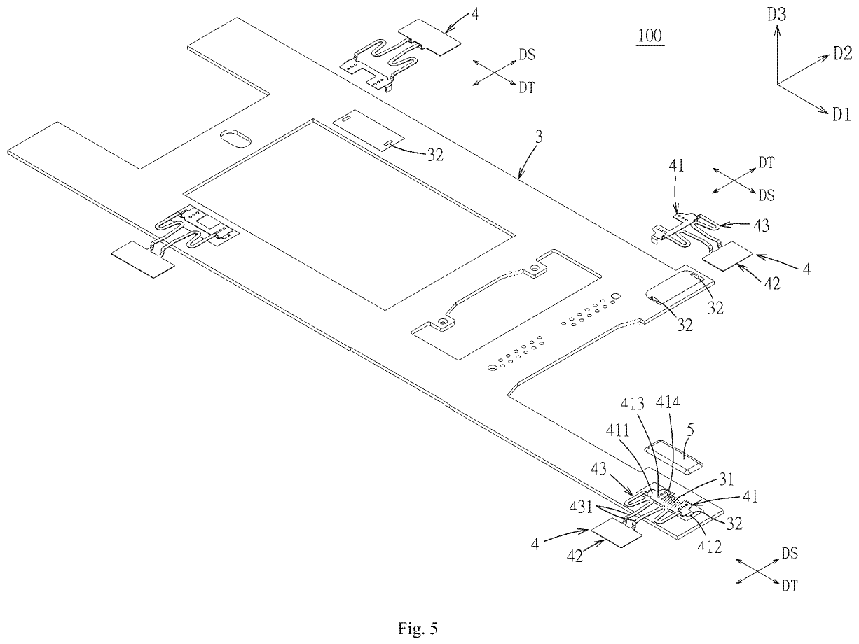

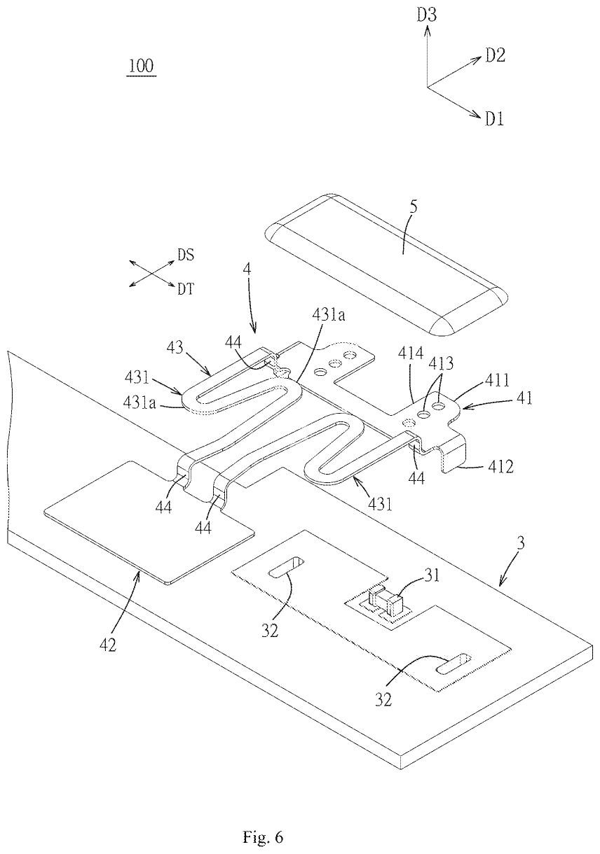

Referring to FIG. 2 to FIG. 6, the carrying tray 1 extends along a front-rear direction D1 (in which an arrow pointing direction is front and an opposite direction is rear) and a left-right direction D2 (in which an arrow pointing direction is right and an opposite direction is left), is adapted to be provided on the battery set 200 along an up-down direction D3 (in which an arrow pointing direction is up and an opposite direction is down), and is made of an insulative material. In the first embodiment, the carrying tray 1 has two tray bodies 11 which are integrally connected along the left-right direction D2 side-by-side and respectively correspond to the two rows of the batteries 201, it is noted that, the number of the tray body 11 of the carrying tray 1 may correspond to the row number of batteries 201, may be any number, and is not limited to the first embodiment. Each tray body 11 has two busbar mounting portions 111 which each extend along the front-rear direction D1 and which are spaced apart from each other in the left-right direction D2, are arranged side-by side and penetrate in the up-down direction D3, and a circuit board mounting portion 112 which extends along the front-rear direction D1 and is positioned between the two busbar mounting portions 111, each busbar mounting portion 111 has a plurality of busbar mounting grooves 111a which are arranged along the front-rear direction D1. In the first embodiment, the plurality of busbars 2 are divided into four rows in the left-right direction D2 in which each row is arranged along the front-rear direction D1, and the plurality of busbars 2 are correspondingly provided over the busbar mounting grooves 111a of the busbar mounting portions 111 of the two tray bodies 11 respectively, each busbar 2 has a plurality of battery connection portions 21 which are arranged along the front-rear direction D1 and are adapted to be connected with electrodes of the batteries 201, and a plurality of buffering portion 22 which each are positioned between two adjacent battery connection portions 21, upwardly arch and extend along the left-right direction D2. For example, the battery connection portion 21 may be connected with the electrode of the battery 201 by welding, in turn the plurality of batteries 201 are connected in series by the plurality of busbars 2.

Moreover, one busbar 2′ straddling the two rows of the batteries 201 has a plurality of battery connection portions 21 which are arranged as two rows along the left-right direction D2, in which each row is arranged along the front-rear direction D1, and are connected with the electrodes of the corresponding batteries 201, and a plurality of buffering portion 22 which each are connected between two adjacent battery connection portions 21 and upwardly arch, the two rows of the batteries 201 are connected with each other in series through the busbar 2′ straddling the two rows of the batteries 201. In addition, two busbars 2″ respectively positioned adjacent to two ending points of a whole circuit in series each further has a providing portion 23 which extends out from the battery connection portion 21, the providing portion 23 is provided with an output connection port 24 as a power output ending point.

It is noted that, in the first embodiment, the circuit board 3 is a flexible circuit board, but in other varied implementing manners, the circuit board 3 also may be replaced by a rigid circuit board (a printed circuit board), and is not limited to the first embodiment. The two circuit boards 3 are respectively provided on the two circuit board mounting portions 112 of the two tray bodies 11 and respectively correspond to the busbars 2 positioned on the two tray bodies 11.

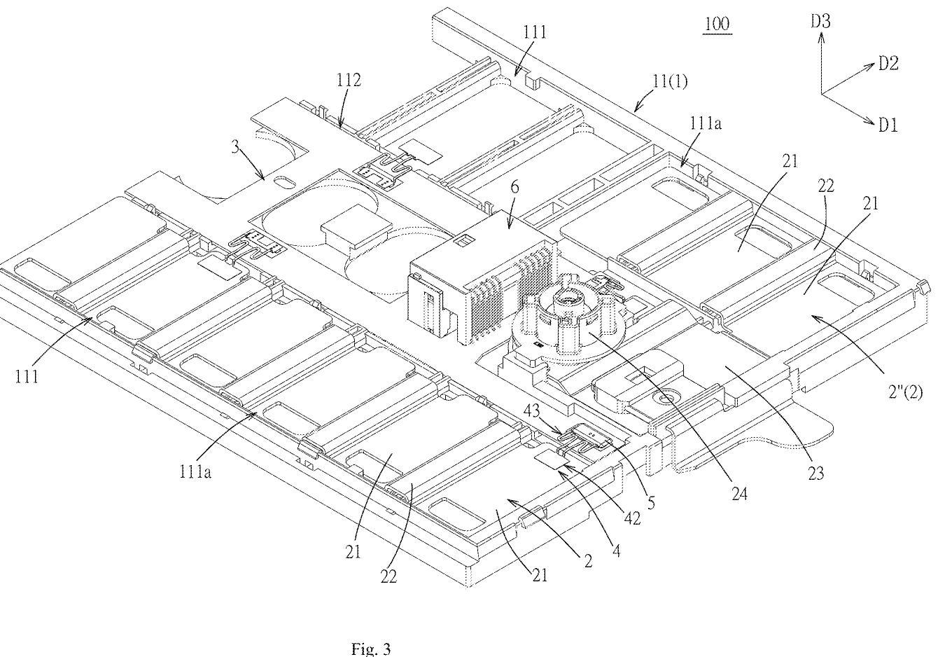

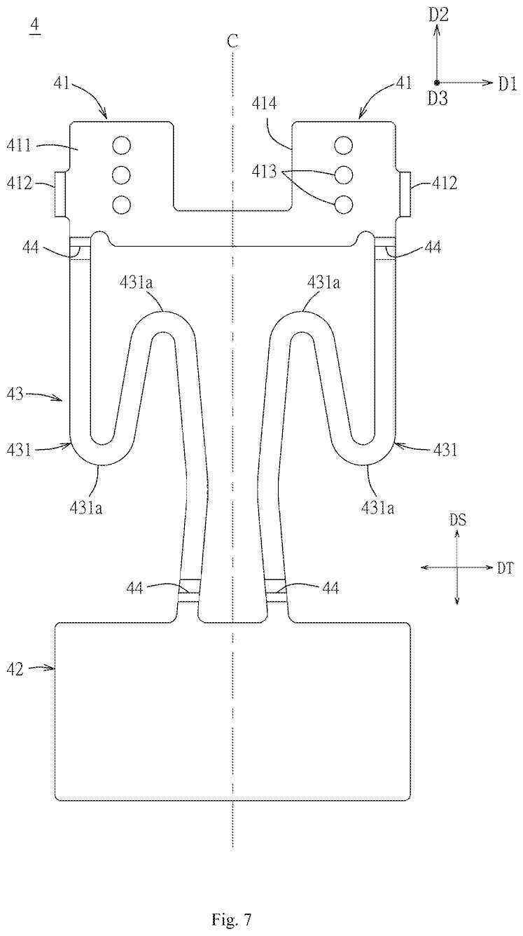

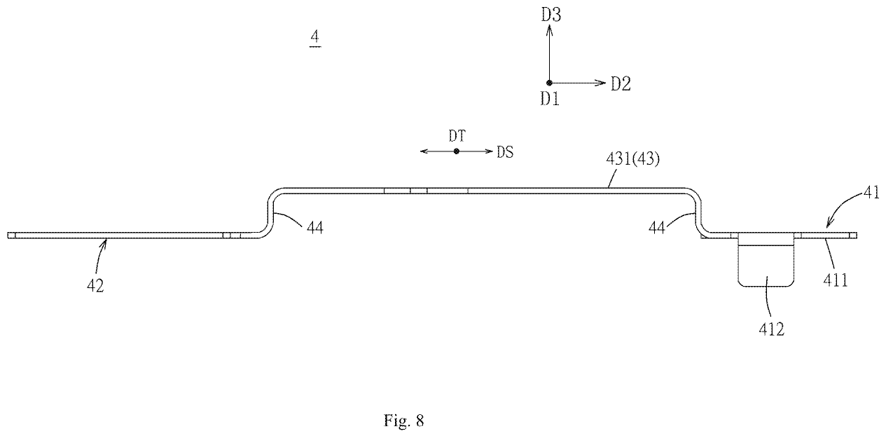

Referring to FIG. 3 and FIG. 5 to FIG. 8, the plurality of bridging pieces 4 are connected between the corresponding busbars 2 and the two circuit boards 3, so that the two circuit boards 3 collect information, such as voltage, temperature and the like, of the plurality of busbars 2 via the plurality of bridging pieces 4. Each bridging piece 4 has a circuit board connection segment 41 and a busbar connection segment 42 which are arranged along a straight direction DS and are respectively connected to the corresponding circuit board 3 and the corresponding busbar 2, and a buffering segment 43 which is positioned between the circuit board connection segment 41 and the busbar connection segment 42. For example, the circuit board connection segment 41 and the busbar connection segment 42 may be respectively connected with the corresponding circuit board 3 and the corresponding busbar 2 by welding, but the present disclosure is not limited thereto.

The buffering segment 43 includes at least two buffering strips 431, specifically, in the first embodiment, the buffering segment 43 includes two buffering strips 431, the two buffering strips 431 are constructed as symmetry in a transverse direction DT with respect to a central line C extending along the straight direction DS. In addition, in the first embodiment, in each bridging piece 4 corresponding to each circuit board 3, the straight directions DS of most of the bridging pieces 4 are parallel to the left-right direction D2 and the transverse directions DT of the most of the bridging pieces 4 are parallel to the front-rear direction D1, the straight direction DS of only one bridging piece 4 is parallel to the front-rear direction D1 and the transverse direction DT of the only one bridging piece 4 is parallel to the left-right direction D2, but it is noted that, a placement orientation of the bridging piece 4 may be adjusted according to relative positions between the circuit board 3 and the busbar 2, and is not limited to the first embodiment.

Each buffering strip 431 has at least one curving portion, but each buffering strip 431 of the first embodiment has at least two straight direction curving portions 431a which are positioned in the same plane and continuously curve reversely relative to each other in the straight direction DS, and, there are steps between a plane where the buffering segment 43 is present and a plane where the circuit board connection segment 41 is present and a plane where the busbar connection segment 42 is present, for example, the plane where the buffering segment 43 is present is higher than the plane where the circuit board connection segment 41 is present and the plane where the busbar connection segment 42 is present, but in other implementing manners, the plane where the buffering segment 43 is present also may be lower than the plane where the circuit board connection segment 41 is present and the plane where the busbar connection segment 42 is present, so the present disclosure is not limited thereto, two ends of each buffering strip 431 of the buffering segment 43 are respectively connected to the circuit board connection segment 41 and the busbar connection segment 42 via two step connecting portions 44. Moreover, the two step connecting portions 44 connected to the circuit board connection segment 41 are positioned at outer sides relative to the two step connecting portions 44 connected to the busbar connection segment 42, the two step connecting portions 44 connected to the busbar connection segment 42 are positioned at inner sides relative to the two step connecting portions 44 connected to the circuit board connection segment 41, the two straight direction curving portions 431a of each buffering strip 431 are positioned between the step connecting portion 44 connected to the circuit board connection segment 41 and the step connecting portion 44 connected to the busbar connection segment 42. The two straight direction curving portions 431a can compensate relative movement between the circuit board connection segment 41 and the busbar connection segment 42 along the straight direction DS, the transverse direction DT and the up-down direction D3, the two step connecting portions 44 raise the buffering segment 43 to be capable of increasing compensation for relative movement and a space between the circuit board connection segment 41 and the busbar connection segment 42 along the up-down direction D3. And, the two buffering strips 431 which are separated from each other can strengthen flexibility of the buffering segment 43.

Moreover, in the first embodiment, the circuit board connection segment 41 of the bridging piece 4 has a plate 411, a welding leg 412 integrally formed downwardly from an edge of the plate 411, a plurality of welding apertures 413 formed in the plate 411, and an opening 414 formed to an edge of the plate 411 and used to receive sensor 31 which is provided to the circuit board 3. Each circuit board 3 is formed with a welding insertion hole 32 corresponding to the welding leg 412, the welding leg 412 and the welding insertion hole 32 which cooperate with each other and the welding apertures 413 can strengthen welding holding force after welded. The sensor 31 provided in the opening 414 may be a temperature sensor or a negative temperature coefficient (NTC) thermistor. In addition, for example, the sensor 31 and the corresponding circuit board connection segment 41 may be further together covered by a thermal conductive adhesive 5. In varied embodiments, if there is not the sensor 31 at a position where the bridging piece 4 is provided, the opening 414 of the bridging piece 4 may be omitted.

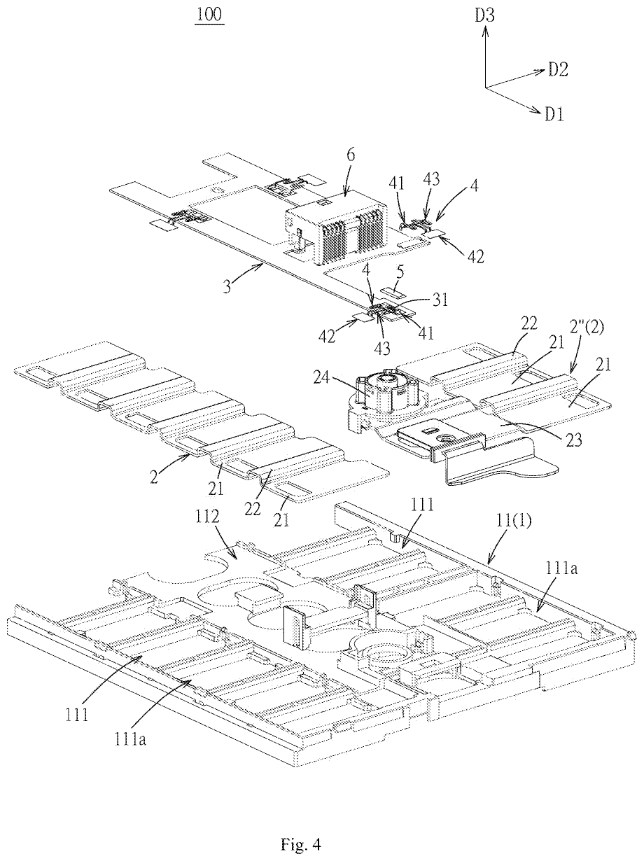

Referring to FIG. 3 and FIG. 4, in addition, each circuit board 3 is provided with a connector 6 thereon, the two circuit boards 3 can collect state information (voltage, temperature and the like) of the two rows of the batteries 201 (see FIG. 1) of the battery set 200 via the plurality of bridging pieces 4, and can transmit the state information to a battery management device (not shown) which is mated with the two connectors 6 via the two connectors 6 which are provided on the two circuit boards 3 respectively.

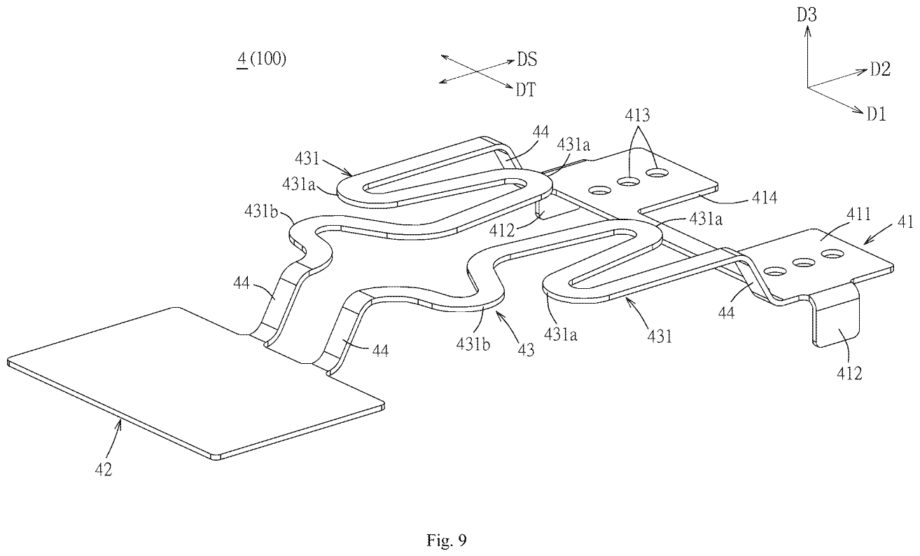

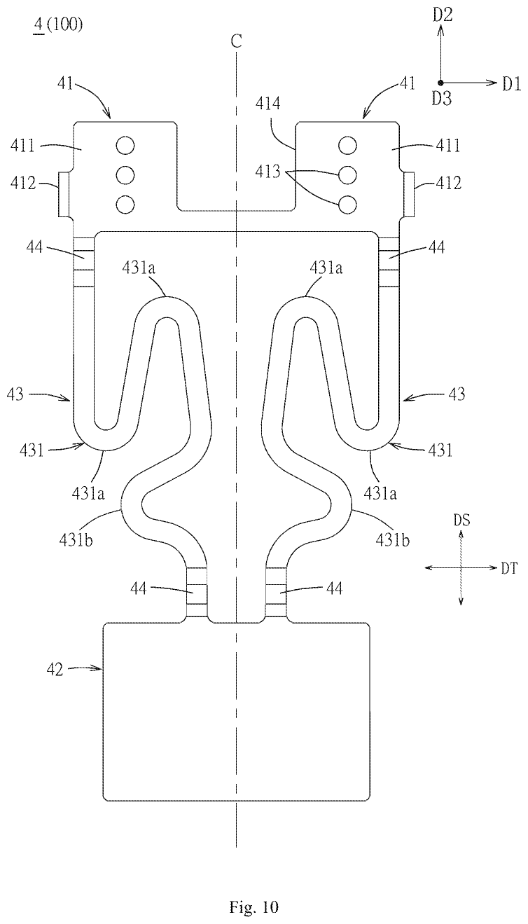

Referring to FIG. 9 and FIG. 10, a second embodiment of the battery connection module 100 of the present disclosure differs from the first embodiment in that, each buffering strip 431 further has at least one transverse curving portion 431b which are spaced apart from the two straight direction curving portions 431a and protrudes laterally and outwardly along the transverse direction DT. The transverse curving portion 431b can increase compensation for relative movement between the circuit board connection segment 41 and the busbar connection segment 42.

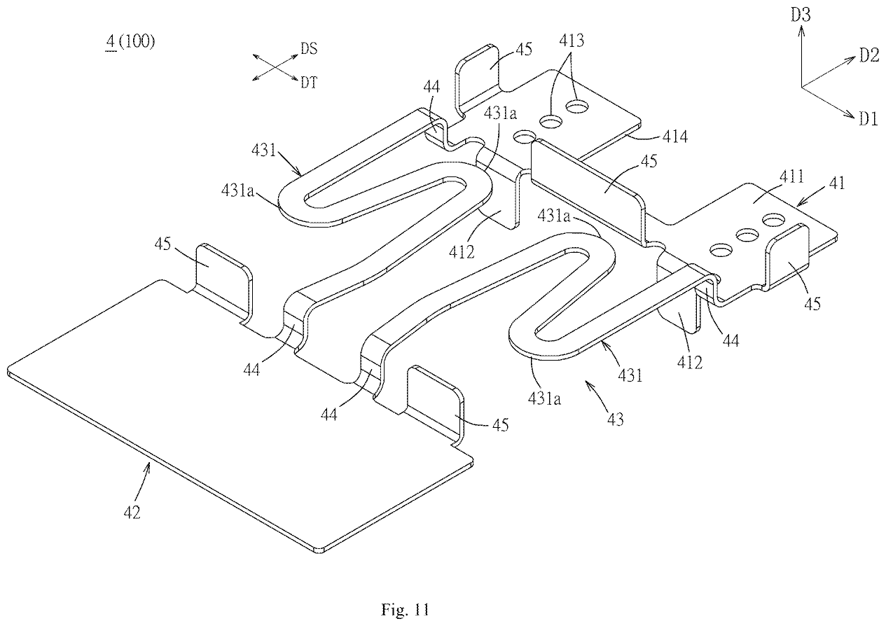

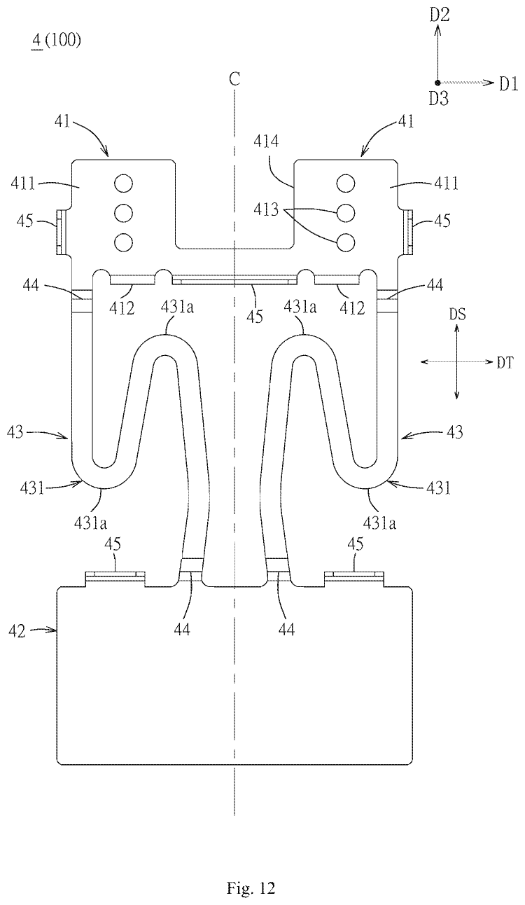

Referring to FIG. 11 and FIG. 12, a third embodiment of the battery connection module 100 of the present disclosure differs from the first embodiment in that, the bridging piece 4 further has a plurality of protective pieces 45 which are integrally formed to the circuit board connection segment 41 and the busbar connection segment 42 adjacent to the buffering segment 43 and protrude toward the plane where the buffering segment 43 is present, the plurality of protective pieces 45 can avoid unintentional external force applying to the buffering strip 431 of the buffering segment 43 to damage the buffering strip 431 of the buffering segment 43.

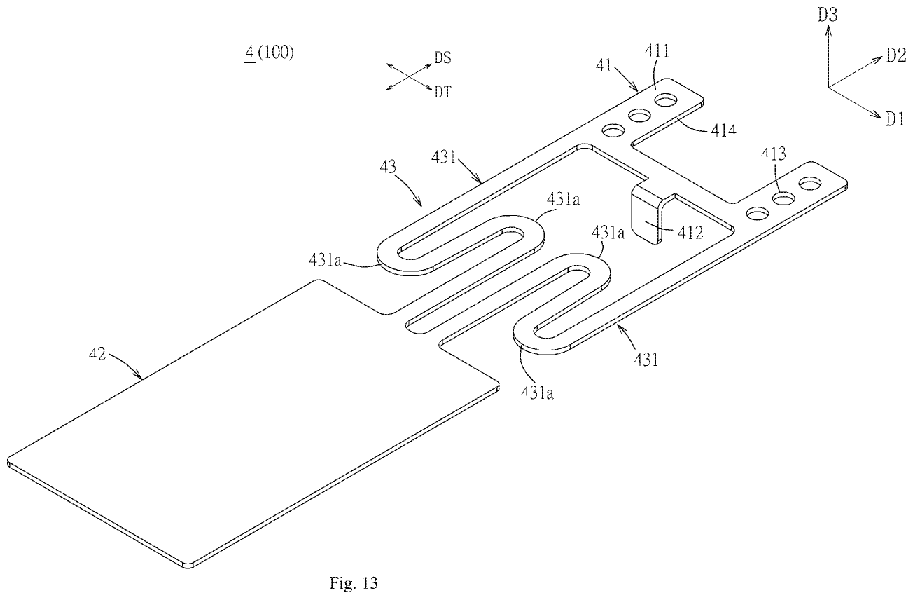

Referring to FIG. 13, a fourth embodiment of the battery connection module 100 of the present disclosure differs from the first embodiment of in that, the plane where the buffering segment 43 is present is positioned in the same plane with the plane where the circuit board connection segment 41 is present and the plane where the busbar connection segment 42 is present.

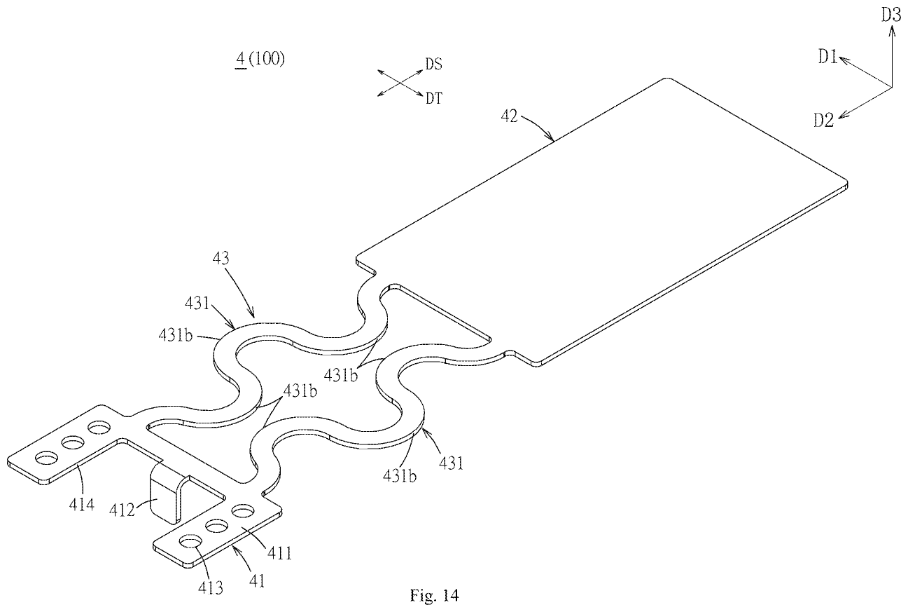

Referring to FIG. 14, a fifth embodiment of the battery connection module 100 of the present disclosure differs from the fourth embodiment in that, each buffering strip 431 has at least two transverse curving portions 431b which are positioned in the same plane and alternately protrude inwardly or outwardly in the transverse direction DT, the buffering strip 431 of the fifth embodiment has three transverse curving portions 431b.

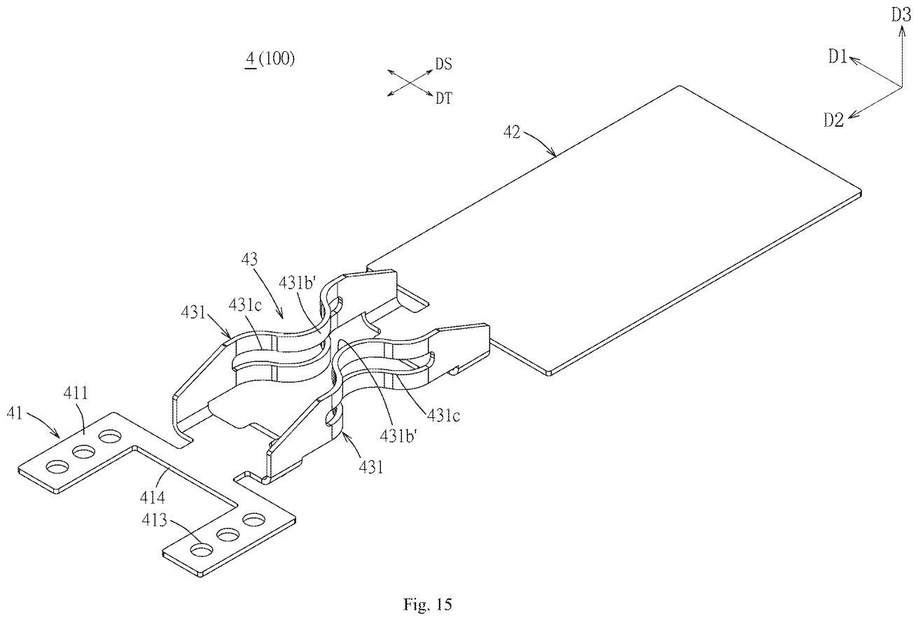

Referring to FIG. 15, a sixth embodiment of the battery connection module 100 of the present disclosure differs from the fourth embodiment in that, the plane where each buffering strip 431 of the buffering segment 43 is present is perpendicular to the plane where the circuit board connection segment 41 is present and the plane where the busbar connection segment 42 is present. And, the plane where each buffering strip 431 of the buffering segment 43 is present is toward the transverse direction DT, each buffering strip 431 has a transverse curving portion 431b′ which protrudes inwardly in the transverse direction DT and an opened groove 431c which is formed to penetrate along the transverse direction DT and extend along the straight direction DS. The opened groove 431c can strengthen flexibility of each buffering strip 431, and thus promote compensation capability of the bridging piece 4 for relative movement between the corresponding circuit board 3 and the busbar 2 and expansion of the corresponding battery 201.

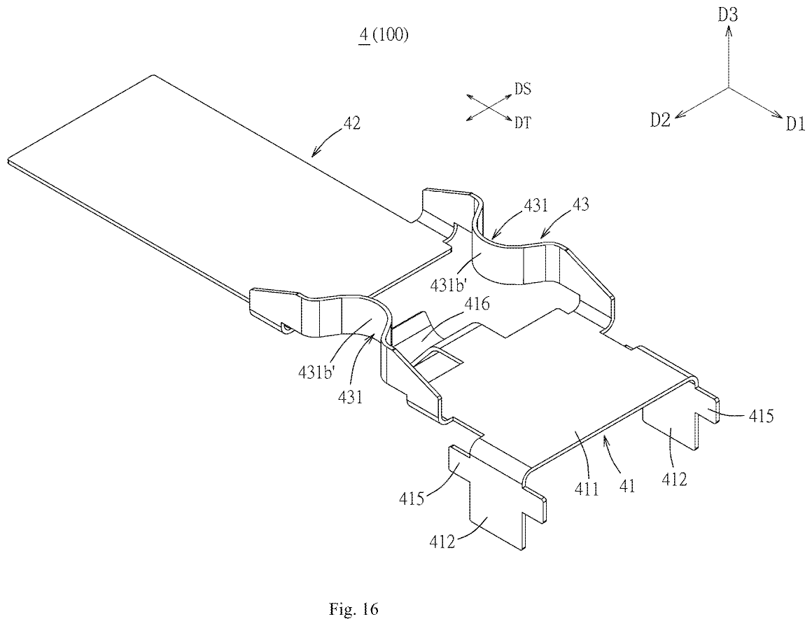

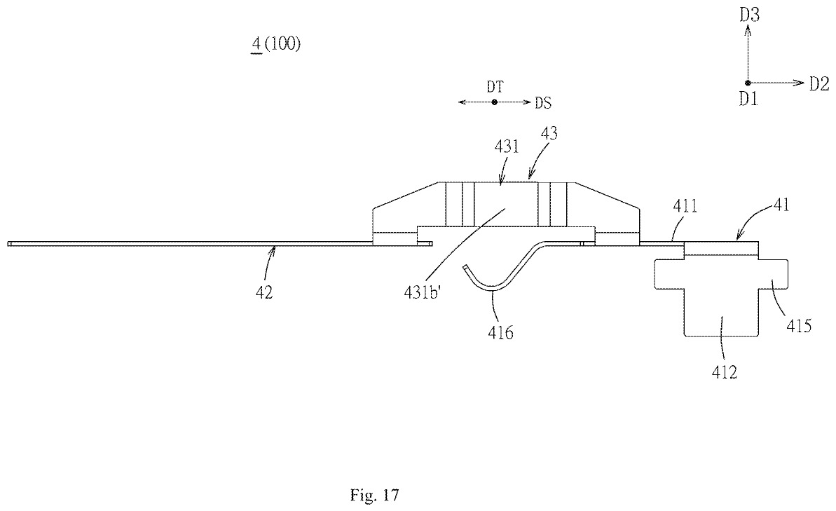

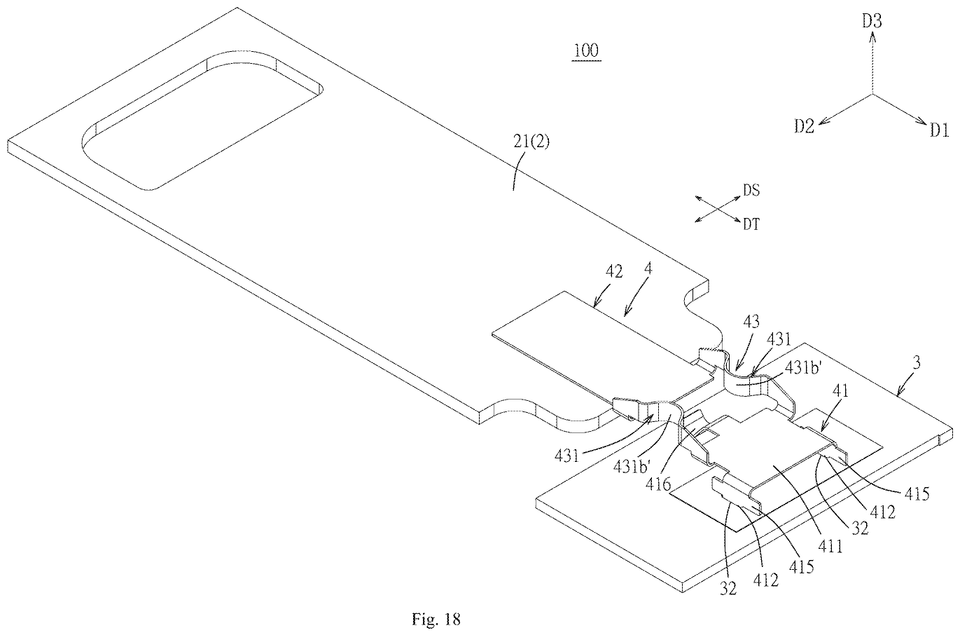

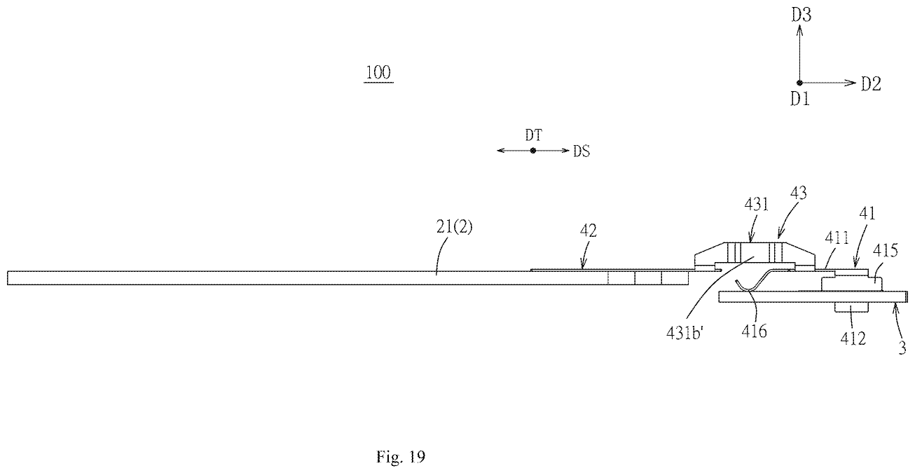

Referring to FIG. 16 to FIG. 19, a seventh embodiment of the battery connection module 100 of the present disclosure differs from the sixth embodiment of in that, the bridging piece 4 of the circuit board connection segment 41 further has two raising legs 415 which are formed downwardly to the plate 411 and are used to be bridged onto the circuit board 3 and a supporting elastic piece 416 which is downwardly formed to the plate 411 and is used to abut against the circuit board 3. The welding leg 412 is formed to a tip of the raising leg 415, a width of the raising leg 415 is larger than a width of the welding leg 412. The two raising legs 415 and the supporting elastic piece 416 raise the plate 411 and make the plate 411 and the circuit board 3 spaced apart from each other by a certain distance, such a connection manner can further lower risk of breaking apart at a connected location in comparison with a face-to-face connection manner between the plate 411 of the circuit board connection segment 41 and the circuit board 3.

In conclusion, the battery connection module 100 of the present disclosure provides a bridging piece 4 which has higher deformation capability and better anti-vibration effect, the buffering segment 43 of the bridging piece 4 can compensate relative movement between the circuit board connection segment 41 and the busbar connection segment 42, thereby promoting compensation capability of the bridging piece 4 for relative movement between the corresponding circuit board 3 and the busbar 2 and expansion of the corresponding batteries 201. Furthermore, the welding apertures 413 and the welding leg 412 of the circuit board connection segment 41 of the bridging piece 4 promote welding holding force between the circuit board connection segment 41 of the bridging piece 4 and the circuit board 3.

However, the above description is only for the embodiments of the present disclosure, and it is not intended to limit the implementing scope of the present disclosure, and the simple equivalent changes and modifications made according to the claims and the contents of the specification are still included in the scope of the present disclosure.

1. A battery connection module adapted to connect a plurality of batteries, the battery connection module comprising:
busbars used to be connected to the batteries;
a circuit board; and
bridging pieces connected between the corresponding busbars and the circuit board, each bridging piece having a circuit board connection segment and a busbar connection segment which are arranged along a straight direction and are respectively connected to the circuit board and the corresponding busbar and a buffering segment which is positioned between the circuit board connection segment and the busbar connection segment, the buffering segment comprising at least two buffering strips, the at least two buffering strips being constructed as symmetry in a transverse direction with respect to a central line extending along the straight direction, each buffering strip having at least one curving portion.

2. The battery connection module of claim 1, wherein there are steps between a plane where the buffering segment is present and a plane where the circuit board connection segment is present and a plane where the busbar connection segment is present, two ends of each buffering strip of the buffering segment are respectively connected to the circuit board connection segment and the busbar connection segment via two step connecting portions.

3. The battery connection module of claim 2, wherein the buffering segment include two buffering strips, each buffering strip has at least two straight direction curving portions which are positioned in the same plane and continuously curve reversely relative to each other in the straight direction.

4. The battery connection module of claim 3, wherein the two step connecting portions connected to the circuit board connection segment are positioned at outer sides relative to the two step connecting portions connected to the busbar connection segment, the two step connecting portions connected to the busbar connection segment are positioned at inner sides relative to the two step connecting portions connected to the circuit board connection segment, the at least two straight direction curving portions of each buffering strip are positioned between the step connecting portion connected to the circuit board connection segment and the step connecting portion connected to the busbar connection segment.

5. The battery connection module of claim 3, wherein each buffering strip further has at least one transverse curving portion which is spaced apart from the at least two straight direction curving portions and protrudes laterally and outwardly along the transverse direction.

6. The battery connection module of claim 2, wherein the bridging piece further has a plurality of protective pieces which are integrally formed to the circuit board connection segment and the busbar connection segment and protrude toward the plane where the buffering segment is present.

7. The battery connection module of claim 1, wherein a plane where the buffering segment is present is positioned in the same plane with a plane where the circuit board connection segment is present and a plane where the busbar connection segment is present.

8. The battery connection module of claim 7, wherein the buffering segment comprises two buffering strips, each buffering strip has at least two straight direction curving portions which are positioned in the same plane and continuously curve reversely relative to each other in the straight direction.

9. The battery connection module of claim 7, wherein the buffering segment comprises two buffering strips, each buffering strip has at least two transverse curving portions which are positioned in the same plane and alternately protrude inwardly or outwardly in the transverse direction.

10. The battery connection module of claim 1, wherein a plane where each buffering strip of the buffering segment is present is perpendicular to a plane where the circuit board connection segment is present and a plane where the busbar connection segment is present.

11. The battery connection module of claim 10, wherein each buffering strip is formed with an opened groove.

12. The battery connection module of claim 1, wherein the circuit board connection segment of the bridging piece has a plate and two raising legs which are formed to the plate and are used to be bridged onto the circuit board, the two raising legs raise the plate and make the plate and the circuit board spaced apart from each other by a certain distance.

13. The battery connection module of claim 12, wherein the circuit board connection segment of the bridging piece further has a supporting elastic piece which is formed to the plate and is used to abut against the circuit board, the supporting elastic piece raises the plate and makes the plate and the circuit board spaced apart from each other by the certain distance.

14. The battery connection module of claim 1, wherein the circuit board connection segment of the bridging piece has a plurality of welding apertures.

15. The battery connection module of claim 1, wherein the circuit board connection segment of the bridging piece has a welding leg, the circuit board is formed with a welding insertion hole corresponding to the welding leg.

16. The battery connection module of claim 1, wherein the circuit board connection segment of the bridging piece has an opening used to provide a sensor therein.
